(19) United States
(12) Patent Application Publication
(10) Pub. No.: US 2021/0376714 A1
(43) Pub. Date: Dec. 2, 2021

(54) PFC Controller with Multi-Function Node, Related PFC Circuit and Control Method

(71) Applicant: Leadtrend Technology Corporation, Zhubei City (TW)

(72) Inventors: Ming Chang TSOU, Zhubei City (TW); Kuan-Hsien CHOU, Zhubei City (TW); Yao-Tsung CHEN, Zhubei City (TW)

(21) Appl. No.: 17/176,242

(22) Filed: Feb. 16, 2021

(30) Foreign Application Priority Data
Jun. 1, 2020 (TW) 109118312

(51) Int. Cl. H02M 1/42; H02M 1/32; G01R 19/165; G01R 19/175; H03K 5/24

(52) U.S. Cl. CPC H02M 1/4233; H02M 1/32; H02M 2001/0009; G01R 19/175; H03K 5/24; G01R 19/16538

(57) ABSTRACT

A PFC circuit uses a single multifunctional node to detect an inductor current when a power switch is turned ON and a zero-current moment when the power switch is turned OFF. The power switch has a drain connected to an inductor, a source connected to a current-sense resistor, and a gate controlled by a PFC controller with the multifunctional node. A signal-integration circuit is electrically coupled between the drain and the source, to provide a multifunctional signal at the multifunctional node. The PFC controller comprises a first comparator and a zero-current detector. The first comparator compares the multifunctional signal with a first reference signal when the PFC controller turns ON the power switch, to provide over-current protection. The zero-current detector decides, in response to the multifunctional signal when the PFC controller turns OFF the power switch, a zero-current moment when an inductor current flowing through the inductor is about zero.

### CROSS-REFERENCE TO RELATED APPLICATION

This application claims priority to and the benefit of Taiwan Application Series Number 109118312 filed on Jun. 1, 2020, which is incorporated by reference in its entirety.

### BACKGROUND

The present disclosure relates generally to active power-factor correction (PFC), and more particularly to active PFC circuits and relevant control methods that use a multifunctional signal at a multifunctional node for both over current protection and zero current detection.

PFC is a technique to increase the power factor of a load powered by an AC power source. PFC mainly modifies output current from the AC power source to the load, making the input current substantially in phase with the AC voltage of the AC power source. The maximum of power factor of a load is 1, meaning that the load to the AC power source is seemingly a pure resistor. A power supply with a low or bad power factor may harshly drain a huge amount of current from an AC power source in a very short time, and hardly utilizes the full power that the AC power source can supply. PFC may change the output current of the AC power source, to smooth its waveform and to increase its power factor.

FIG. 1 is conventional active PFC circuit 100, with a topology of booster. PFC controller 102 turns ON and OFF power switch 104, controlling the waveform of inductor current I_{L} flowing through inductor L, in order to make the average of inductor current I_{L} substantially have a rectified sinusoidal waveform in phase with the voltage amplitude of AC power source V_{AC-IN}, which comes from a wall outlet for example. Diode D1 provides rectification, so that inductor current I_{L} charges output capacitor COUT to build up output voltage V_{OUT} when power switch 104 is turned OFF.

### BRIEF DESCRIPTION OF THE DRAWINGS

Non-limiting and non-exhaustive embodiments of the present invention are described with reference to the following drawings. In the drawings, like reference numerals refer to like parts throughout the various figures unless otherwise specified. These drawings are not necessarily drawn to scale. Likewise, the relative sizes of elements illustrated by the drawings may differ from the relative sizes depicted.

The invention can be more fully understood by the subsequent detailed description and examples with references made to the accompanying drawings, wherein:

FIG. 1 is a conventional active PFC circuit;

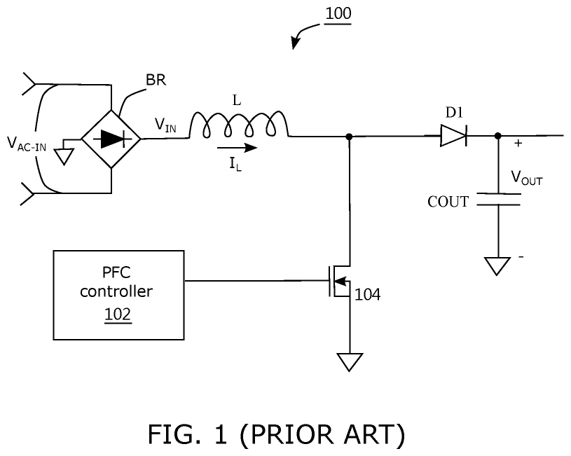

FIG. 2 demonstrates an active PFC circuit according to embodiments of the invention;

FIG. 3 shows gate signal V_{G}, current-sense signal V_{CS}, inductor current I_{L}, drain signal V_{D}, and multifunctional signal V_{CS/ZCD} of FIG. 2; and

FIG. 4 demonstrates PFC controller 202 in FIG. 2.

### DETAILED DESCRIPTION

According to embodiments of the invention, a PFC controller controls a power switch connected in series with an inductor to perform PFC. The PFC controller is a packaged monolithic integrated circuit chip, having a multifunctional pin electrically connected to a signal-integration circuit, which connects to both a drain and a source of the power switch. Based on a multifunctional signal at the multifunctional pin, the PFC controller detects an inductor current through the inductor when the power switch is turned ON, and detects a zero-current moment when the power switch is turned OFF, where the zero-current moment represents the moment when the inductor current drops to about zero. When the power switch is turned OFF, the PFC controller can also provide protections against disasters possibly caused by abnormal conditions.

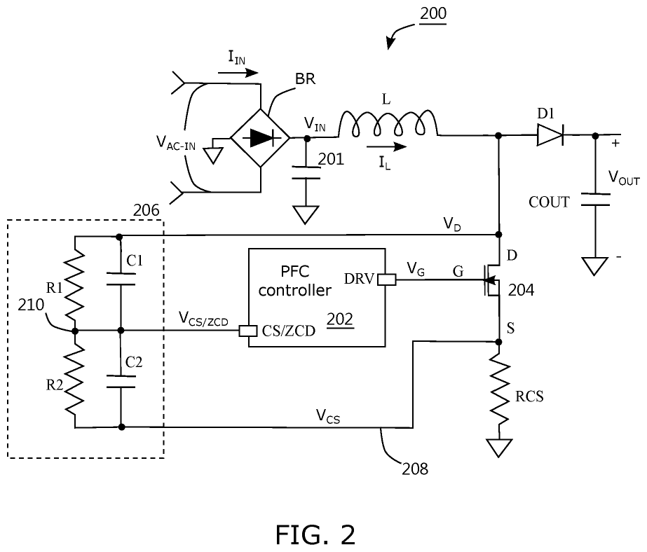

FIG. 2 demonstrates active PFC circuit 200, having a topology of booster, according to embodiments of the invention. PFC circuit 200 has, but is not limited to have, bridge rectifier BR, decouple capacitor 201, inductor L, PFC controller 202, power switch 204, signal-integration circuit 206, current-sense resistor RCS, diode D1, and output capacitor COUT. Power switch 204, a NMOS transistor for example, has drain D electrically connected to both inductor L and diode D1, where drain signal V_{D} is at drain D. Current-sense resistor RCS is connected between a ground line and source S of power switch 204, and current-sense signal V_{CS} is at node 208. When power switch 204 is turned ON, performing a short circuit between drain D and source S, current-sense signal V_{CS} can represent inductor current I_{L} through inductor L.

Bridge rectifier BR provides full-wave rectification, to provide a direct-current (DC) input power source V_{IN} and a ground line based on AC power source V_{AC-IN}. Inductor L is electrically connected between input power source V_{IN} and drain D. The combination of inductor L and decouple capacitor 201 results in a low-pass filter, making input current I_{IN} smooth. According to embodiments, PFC controller 202 is a monolithic integrated circuit chip packaged with pins, and each pin is also a node for interconnecting electric devices. PFC controller 202 utilizes pulse-width-modulation technology to provide at drive pin DRV gate signal V_{G}. Gate signal V_{G}, as it controls gate G of power switch 204, turns ON and OFF power switch 204 to regulate output voltage V_{OUT} and at the same time to make input current I_{IN} substantially in phase with the voltage of AC power source V_{AC-IN}, thereby achieving PFC. According to embodiments of the invention, PFC circuit 200 could operate in boundary mode, discontinuous conduction mode (DCM) or burst mode. Output voltage V_{OUT} could supply power to loads or other power converters not shown in FIG. 2.

Signal-integration circuit 206 is electrically connected to both drain D and source S, capable of integrating current-sense signal V_{CS} and drain signal V_{D} to generate multifunctional signal V_{CS/ZCD} at multifunctional pin CS/ZCD of PFC controller 202. Signal-integration circuit 206 has a pair of resistors, R1 and R2, and a pair of capacitors Cl and C2. Resistors R1 and R2 are connected in series between drain D and source S, and so are capacitors C1 and C2. Joint 210 electrically connects resistors R1 and R2 and capacitors C1 and C2 to multifunctional pin CS/ZCD. Multifunctional signal V_{CS/ZCD} represents current-sense signal V_{CS} when power switch 204 is turned ON, because in the meantime drain signal V_{D} is about the same with current-sense signal V_{CS}. Therefore, based on the information that multifunctional signal V_{CS/ZCD} carries when power switch 204 is ON, PFC controller 202 can acknowledge whether inductor current I_{L} is too much and renders corresponding protection. On the occasion when power switch 204 is OFF, performing an open circuit between drain D and source S, multifunctional signal V_{CS/ZCD} can represent drain signal V_{D} because in the meantime current-sense signal V_{CS} is about zero. Drain signal V_{D} reflects output voltage V_{OUT} when diode D1 forwards inductor current I_{L} to output capacitor COUT, and drain signal V_{D} starts oscillating after inductor current I_{L} depletes or becomes zero. The moment when inductor current I_{L} becomes zero is hereinafter referred to as zero-current moment tZCD. Accordingly, based on the information that multifunctional signal V_{CS/ZCD} carries when power switch 204 is OFF, PFC controller 202 can detect output voltage V_{OUT} and zero-current moment tZCD, to provide corresponding controls.

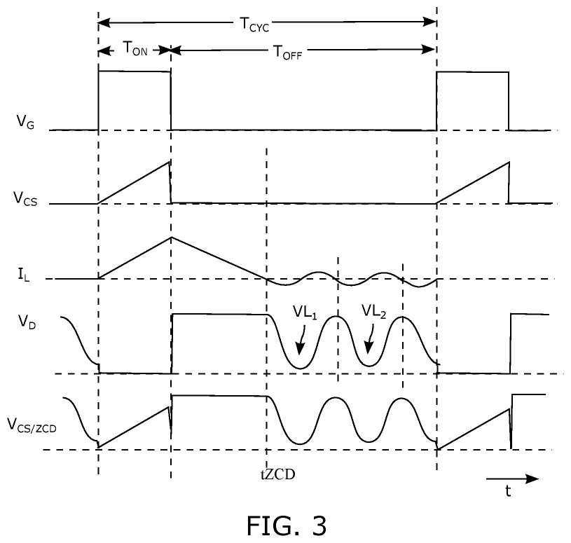

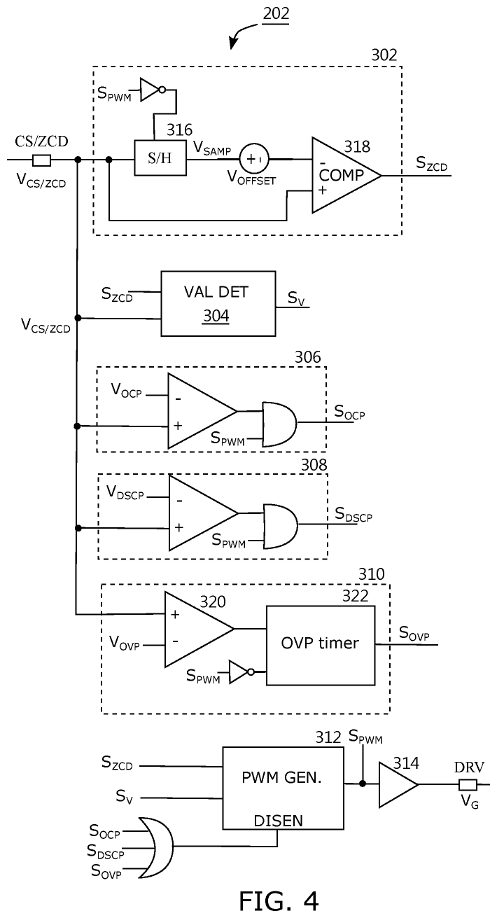

FIG. 3 shows gate signal V_{G}, current-sense signal V_{CS}, inductor current I_{L}, drain signal V_{D}, and multifunctional signal V_{CS/ZCD} of FIG. 2. FIG. 4 demonstrates PFC controller 202 in FIG. 2, including zero-current detector 302, valley detector 304, over-current detector 306, diode-short detector 308, over-voltage detector 310, pulse-width modulator 312, and driver 314.

Please reference both FIGS. 3 and 4. One switching cycle T_{CYC} consists of one ON time T_{ON} and one OFF time T_{OFF}. ON time T_{ON} is a period when gate signal V_{G} is “1” in logic and makes power switch 204 a short circuit between drain D and source S. In the opposite, OFF time T_{OFF} is a period when gate signal V_{G} is “0” in logic and makes power switch 204 an open circuit between drain D and source S.

Pulse-width modulator 312 generates PWM signal S_{PWM}, and driver 314, in response to PWM signal S_{PWM}, provides gate signal V_{G} with suitable voltage or current to drive power switch 204. In view of the logic values, gate signal V_{G} and PWM signal S_{PWM} in FIG. 4 are the same. For example, pulse-width modulator 312 determines the duration of ON time T_{ON} in response to a compensation signal, not shown in the drawings, using a technology generally known as constant ON-time control, which controls the duration of ON time T_{ON} regardless of input voltage V_{IN}.

During ON time T_{ON}, power switch 204 performs as a short circuit between drain D and source S. Therefore, inductor current I_{L} and current-sense signal V_{CS} both increase linearly over time. Because drain D electrically shorts to source S, drain signal V_{D} is substantially equal to current-sense signal V_{CS}, making multifunctional signal V_{CS/ZCD} substantially equal to current-sense signal V_{CS} if the input impedance into multifunctional pin CS/ZCD of PFC controller 202 is high. As shown in FIG. 3, current-sense signal V_{CS}, inductor current I_{L} and multifunctional signal V_{CS/ZCD} have similar waveforms during ON time T_{ON}.

Over-current detector 306 in FIG. 4 detects multifunctional signal V_{CS/ZCD} during ON time T_{ON}. For example, during ON time T_{ON}, over-current detector 306 compares multifunctional signal V_{CS/ZCD} with over-current protection (OCP) reference signal V_{OCP}, a predetermined signal. In case that multifunctional signal V_{CS/ZCD} exceeds OCP reference signal V_{OCP}, meaning inductor current I_{L} is over large, over-current detector 306 sends protection signal S_{OCP} to disable pulse-width modulator 312, which in response quickly turns OFF power switch 204 and keeps it constantly OFF ever since. Over-current detector 306 can prevent inductor current I_{L} from being over large due to an over heavy load.

Similar with over-current detector 306, diode-short detector 308 compares multifunctional signal V_{CS/ZCD} with diode-short-circuit protection (DSCP) reference signal V_{DSCP}, another predetermined signal, during ON time T_{ON}. When multifunctional signal V_{CS/ZCD} exceeds DSCP reference signal V_{DSCP}, diode-short detector 308 provides protection signal S_{DSCP} to disable pulse-width modulator 312, which in response quickly turns OFF power switch 204 and keeps it constantly OFF ever since. Diode-short detector 308 is used to protect power switch 204 from conducting over-large current when diode D1 mistakenly becomes a short circuit all the time and constantly clamps drain signal V_{D} at output voltage V_{OUT}.

During OFF time T_{OFF}, current-sense signal V_{CS} is about zero because power switch 204 conducts no current, so multifunctional signal V_{CS/ZCD}, currently in proportion to drain signal V_{D}, can represent drain signal V_{D}, as shown in FIG. 3.

During OFF time T_{OFF}, zero-current detector 302 detects zero-current moment tZCD based on multifunctional signal V_{CS/ZCD}, where zero-current moment tZCD refers to the moment when inductor current I_{L} drops to about 0A, as shown in FIG. 3. Sample-and-hold circuit 316 in FIG. 4 for example samples multifunctional signal V_{CS/ZCD} at a predetermined moment when drain signal V_{D} is expected to be about output voltage V_{OUT}, to hold sample V_{SAMP} which comparator 318 compares multifunctional signal V_{CS/ZCD} with to determine zero-current moment tZCD. For instance, as shown in FIG. 4, if multifunctional signal V_{CS/ZCD} drops to become less than sample V_{SAMP} by offset V_{OFFSET}, zero-current moment tZCD is supposedly detected and pulse S_{ZCD} sent accordingly.

During OFF time T_{OFF} and after zero-current moment tZCD, valley detector 304 detects the occurrences of signal valleys VL₁, VL₂, etc., that drain voltage V_{D} at drain D oscillates to create, and generates signal S_{V} accordingly to pulse-width modulator 312, which is configured to start the next ON time T_{ON} at about the moment when the bottom of a signal valley appears, performing valley switching. Since the bottom of a signal valley means that the voltage difference between drain D and source S is at its minimum, valley switching can reduce conduction loss of power switch 204 and improve conversion efficiency. As shown in FIG. 4, pulse-width modulator 312 turns ON power switch 204 and starts ON time T_{ON} of the next switching cycle T_{CYC} in response to pulse S_{ZCD} and signal S_{V}.

During OFF time T_{OFF} and before zero-current moment tZCD, multifunctional signal V_{CS/ZCD} is in proportion to drain voltage V_{D}, which is about output voltage V_{OUT}, and over-voltage detector 310 checks if multifunctional signal V_{CS/ZCD} is over high to provide over-voltage protection (OVP). Comparator 320 compares multifunctional signal V_{CS/ZCD} with OVP reference signal V_{OVP}. In case that multifunctional signal V_{CS/ZCD} has been exceeding OVP reference signal V_{OVP} for a predetermined period, timer 322 sends protection signal S_{OVP} to disable pulse-width modulator 312, which in response constantly turns OFF power switch 204 to avoid over-high output voltage V_{OUT}.

Accordingly, PFC controller 202, which is in form of a packaged monolithic chip according to embodiments of the invention, uses only multifunctional pin CS/ZCD to provide multiple protections, such as OVP, OCP, and DSCP, and to detect zero-current moment and signal valleys. PFC controller 202 could have a less pin number, which would make the total cost of PFC circuit 200 more attractive to manufacturers.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A power-factor correction circuit, comprising:
an inductor;
a power switch with a drain, a source and a gate, wherein the drain is connected to the inductor;
a current-sense resistor connected between the source and a ground line;
a PFC controller having a multifunctional node and a drive node connected to the gate; and
a signal-integration circuit electrically coupled between the drain and the source, for providing a multifunctional signal at the multifunctional node;
wherein the PFC controller comprises:
a first comparator comparing the multifunctional signal with a first reference signal when the PFC controller turns ON the power switch, to provide over-current protection if the multifunctional signal exceeds the first reference signal; and
a zero-current detector connected to receive the multifunctional signal when the PFC controller turns OFF the power switch, and to decide, in response to the multifunctional signal, a zero-current moment when an inductor current flowing through the inductor is about zero.

2. The power-factor correction circuit as claimed in claim 1, wherein the PFC controller further comprises a second comparator comparing the multifunctional signal with a second reference signal when the PFC controller turns OFF the power switch, to provide over-voltage protection.

3. The power-factor correction circuit as claimed in claim 1, wherein the PFC controller detects a signal valley of the multifunctional signal to turn ON the power switch.

4. The power-factor correction circuit as claimed in claim 1, wherein the signal-integration circuit includes two resistors connected in series between the drain and the source, and a joint between the two resistors is connected to the multifunctional node.

5. The power-factor correction circuit as claimed in claim 1, wherein the signal-integration circuit includes two capacitors connected in series between the drain and the source, and a joint between the two capacitors is connected to the multifunctional node.

6. The power-factor correction circuit as claimed in claim 1, wherein the zero-current detector samples the multifunctional signal to provide a sample when the PFC controller turns OFF the power switch, and comparing the sample with the multifunctional signal to determine the zero-current moment.

7. A PFC controller, comprising:
a driver for driving a power switch with a drain and a source;
a multifunctional node coupled to the drain and the source via a signal-integration circuit, wherein a multifunctional signal is at the multifunctional node;
a zero-current detector connected to the multifunctional node for receiving the multifunctional signal when the PFC controller turns OFF the power switch, and detecting, in response to the multifunctional signal, a zero-current moment when an inductor current flowing through an inductor is about zero; and
an over-current detector coupled to the multifunctional node, for comparing the multifunctional signal with a first reference signal when the driver turns ON the power switch, to turn OFF the power switch and provide over-current protection.

8. The PFC controller as claimed in claim 7, comprising an over-voltage detector, wherein when the driver turns OFF the power switch the over-voltage detector compares the multifunctional signal with a second reference signal to provide over-voltage protection, constantly turning OFF the power switch.

9. The PFC controller as claimed in claim 7, wherein the zero-current detector samples the multifunctional signal to provide a sample when the PFC controller turns OFF the power switch, and compares the sample with the multifunctional signal to determine the zero-current moment.

10. The PFC controller as claimed in claim 7, wherein the zero-current detector sends a zero-current signal indicating the occurrence of the zero-current moment, and the PFC controller further comprises:
a valley detector, for detecting a signal valley of the multifunctional signal in response to the multifunctional signal and the zero-current signal.

11. A control method for PFC, comprising:
controlling a power switch with a drain and a source, wherein the drain is connected to an inductor, and the source is connected to a current-sense resistor;
providing a multifunctional node coupled to the drain and the source via a signal-integration circuit, wherein a multifunctional signal is at the multifunctional node;
turning OFF the power switch and detecting a zero-current moment when an inductor current flowing through an inductor is about zero in response to the multifunctional signal; and
turning ON the power switch and comparing the multifunctional signal with a first reference signal to provide over-current protection and constantly turn OFF the power switch.

12. The control method as claimed in claim 11, comprising:
turning OFF the power switch and comparing the comparing the multifunctional signal with a second reference signal, to provide over-voltage protection and constantly turning OFF the power switch.

13. The control method as claimed in claim 11, comprising:
sampling the multifunctional signal to provide a sample when turning OFF the power switch; and
comparing the sample with the multifunctional signal to determine the zero-current moment.

14. The control method as claimed in claim 11, comprising:
detecting a signal valley of the multifunctional signal in response to the multifunctional signal and a zero-current signal indicating the occurrence of the zero-current moment.
